(19) United States
(12) Patent Application Publication
(10) Pub. No.: US 2018/0164371 A1
(43) Pub. Date: Jun. 14, 2018

(54) APPARATUS AND METHOD FOR PROVIDING DEBUG INFORMATION VIA POWER RAIL IN POWER STATE WHERE DEBUG INTERFACE IS DISABLED

(71) Applicant: QUALCOMM Incorporated, San Diego, CA (US)

(72) Inventors: Paul Morris, Cambridge (GB); Sukanta Panigrahi, Cambridge (GB); John Bruce, Bishops Stortford (GB)

(21) Appl. No.: 15/375,898

(22) Filed: Dec. 12, 2016

(51) Int. Cl. G01R 31/317

(52) U.S. Cl. CPC G01R 31/31705; G01R 31/31721; G01R 31/31713

(57) ABSTRACT

Apparatus and method for providing debug information from an IC to an external equipment via a power rail in a power state where a debug interface is disabled. The apparatus includes a modulator coupled to a power rail; a debug interface configured to be enabled while the IC is operating under a first set of one or more power states, and disabled while the IC is operating under a second set of one or more power states; and a power management unit manager configured to send debug information to the equipment via the debug interface while the IC is operating under the first set of power state(s); and generate a modulation signal for the modulator to modulate a parameter on the power rail with the debug information while the IC is operating under the second set of power state(s), wherein the equipment receives the parameter to obtain the debug information.

### BACKGROUND

### Field

Aspects of the present disclosure relate generally to outputting debug information from an integrated circuit (IC), and in particular, to an apparatus and method for providing debug information from an IC to an external test equipment via a power rail in a power state where a debug interface is disabled.

### Background

An integrated circuit (IC) may send debug information, such as current power state and event that caused the IC to enter the current power state, to an external test equipment via a debug interface. However, in certain low power state, the IC may disable the debug interface. Thus, in such low power state, the IC has no mechanism for sending the debug information to a test equipment. Accordingly, a need to solve this issue is desired.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

An aspect of the disclosure relates to an integrated circuit including a modulator coupled to a power rail; a debug interface configured to be enabled while the IC is operating under a first set of one or more power states, and disabled while the IC is operating under a second set of one or more power states; and a power management unit (PMU) manager configured to: send debug information to an external test equipment via the debug interface while the IC is operating under the first set of one or more power states; and generate a modulation signal for the modulator to modulate a parameter on the power rail with the debug information while the IC is operating under the second set of one or more power states.

Another aspect of the disclosure relates to a method including sending debug information from an integrated circuit (IC) to an external test equipment via a debug interface while the IC is operating under a first set of one or more power states; and generating, within the IC, a parameter on a power rail modulated with debug information while the IC is operating under a second set of one or more power states.

Another aspect of the disclosure relates to an apparatus including means for sending debug information from an integrated circuit (IC) to an external test equipment via a debug interface while the IC is operating under a first set of one or more power states; and means for generating, within the IC, a parameter on a power rail modulated with debug information while the IC is operating under a second set of one or more power states.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIG. 1 illustrates a block diagram of an exemplary integrated circuit (IC) in accordance with an aspect of the disclosure.

FIG. 2 illustrates a block diagram of another exemplary integrated circuit (IC) in accordance with another aspect of the disclosure.

FIG. 3 illustrates a block diagram of another exemplary integrated circuit (IC) in accordance with an aspect of the disclosure.

FIG. 4 illustrates a block diagram of another exemplary integrated circuit (IC) in accordance with another aspect of the disclosure.

FIG. 5 illustrates a block diagram of another exemplary integrated circuit (IC) in accordance with another aspect of the disclosure.

FIG. 6 illustrates a block diagram of another exemplary integrated circuit (IC) in accordance with another aspect of the disclosure.

FIG. 7 illustrates a flow diagram of an exemplary method of outputting debug information from an integrated circuit (IC) in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A System on Chip (SOC) type integrated circuit (IC), such as used in Internet of Things (IoT) devices, may operate under one or more low power states in which one or more IC cores and certain Input/Output (I/O) pads are disabled. In such low power state, the traditional interface, such as Serial Peripheral Interface (SPI), Universal Asynchronous Receiver/Transmitter (UART), or Universal Serial Bus (USB), may not be available for debug purpose. Accordingly, in such low power state, it is difficult or not possible to determine the power state of a Power Management Unit (PMU) and one or more events that led the PMU to enter that power state via the debug interface.

Thus, once the PMU has been commanded to enter the low power state, it is not possible to be sure if it has even reached that power state other than by monitoring the power consumption of the IC. However, if the power consumption is not correct, then it can be very difficult and time consuming to determine the cause in the discrepancy between the low power state and the measured power consumption. This is explained in more detail with reference to the following exemplary implementations.

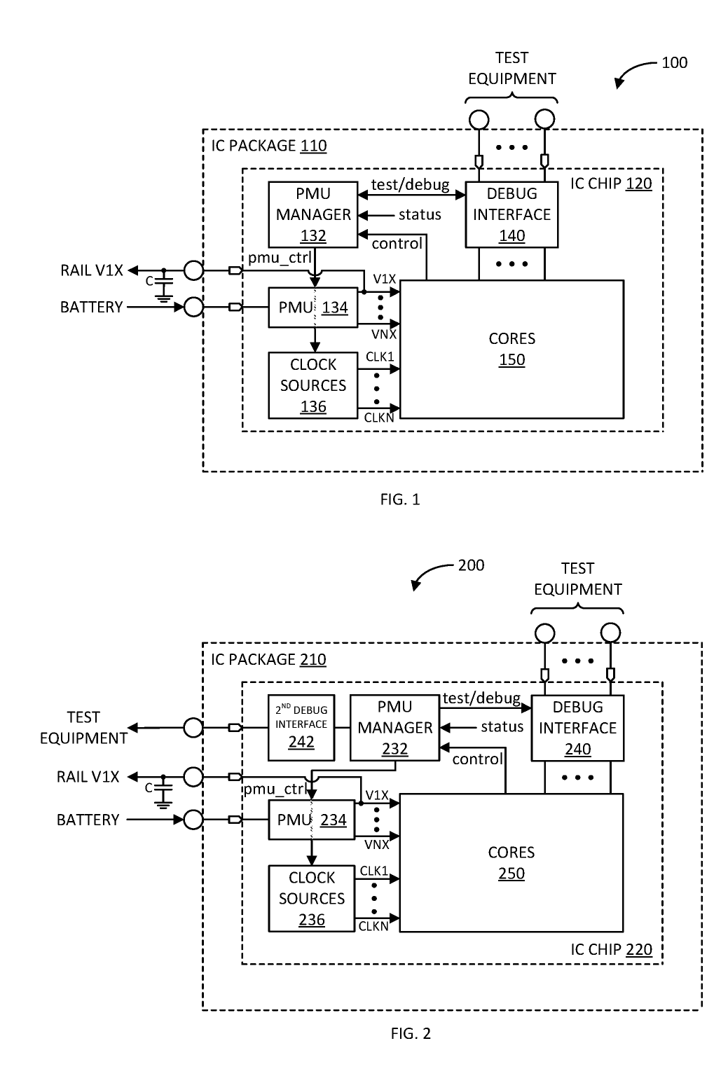

FIG. 1 illustrates a block diagram of an exemplary IC 100 in accordance with an aspect of the disclosure. The IC 100 includes an IC chip 120 situated within an IC package 110. The IC chip 120 includes a PMU manager 132, a PMU 134, a set of clock sources 136, a debug interface 140, and IC cores 150.

Under the control of the PMU manager 132, the PMU 134 generates a set of power rail voltages V1X to VNX based on a battery voltage, and the set of clock sources 136 generate a set of clocks CLK1 to CLKN. The set of power rail voltages V1X to VNX and clocks CLK1 to CLKN are applied to the cores 150, respectively. The voltage level and frequency of the clock applied to a particular core is related to the amount of power drawn by the core. As illustrated, at least one of the power rails (e.g., V1X) is coupled to an IC port (e.g., pin/pad) for connecting a decoupling capacitor C to the power rail.

At least one of the cores 150, such as a central processing unit (CPU) core or other, may send a control command to the PMU manager 132 to configure the PMU 134 in a particular power state. The CPU core may send the command in response to a particular event, such as signal activity in one or more pins of the IC 100 (e.g., a user pressed a button on the IoT device) or a timer generating a trigger signal. Also, the PMU manager 132 may configure the PMU 134 in a particular power state in response to a status signal generated by a sensor (e.g., a temperature sensor for preventing harmful (e.g., overloading) conditions) or an event trigger (e.g., a timer). Additionally, the PMU 134 may be configured in a particular power state via a test command sent to the PMU manager 132 from an external test equipment via the debug interface 140.

In response to the control command, status, or test command, the PMU manager 132 generates a PMU control signal pmu_ctrl to control the PMU 134 and clock sources 136 to generate a particular set of one or more supply voltages V1X to VNX and a particular set of one or more clock signals CLK1 to CLKN corresponding to the requested power state. For instance, if the particular core of the cores 150 needs to perform a demanding task (e.g., a graphics processing unit (GPU) core processing large amounts of video data), the core may request a relatively high power state including a relatively high supply voltage (e.g., VNX) and a relatively high frequency clock source (e.g., CLKN). Whereas another core of the cores 150 may only need to perform a minimal task (e.g., a memory core merely performing data retention), the core may request a relatively low power state including a relatively low supply voltage (e.g., VN1) and a relatively low frequency clock source (e.g., CLK1) (e.g., where VNX>VNX1 and f_{CLKN}>f_{CLK1}).

Additionally, in response to the control command, status, or test command, the PMU manager 132 maintains a log of debug information concerning a history of the power states and events that resulted in the power states, respectively. For example, a GPU core may have requested a particular high power state for performing video processing. In response, the PMU manager 132 logs the particular power state and that the GPU core requested the particular power state. As another example, a temperature sensor or timer may have issued a status command which caused the PMU 134 to enter a certain power state. In response, the PMU manager 132 logs the particular power state and that the temperature sensor or timer requested the particular power state. In a like example, an external test equipment may send a test command to the PMU manager 132 via the debug interface 140 to cause the PMU 134 to enter a particular power state. In response, the PMU manager 132 logs the particular power state and the test command that requested the particular power state.

In certain power states, at least some of the cores 150 and the debug interface 140 are enabled. Thus, in such power states, the PMU manager 132 is able to send the debug information (e.g., power state and event information) to an external test equipment via the debug interface 140.

However, in certain types of ICs, such as used in IoT applications, the IC 100 may be operated in a particular low power state in which at least some of the cores 150 and the debug interface 140 are disabled. In such case, the PMU manager 132 is not able to send debug information to an external test equipment via the debug interface 140, as the interface is disabled. Thus, it is not possible to determine whether in fact the PMU 134 is in the commanded low power state and what event placed the PMU 134 in the current (albeit unknown) power state. Accordingly, debugging and verification of the operation of the IC 100 is difficult in such low power state.

FIG. 2 illustrates a block diagram of another exemplary IC 200 in accordance with another aspect of the disclosure. Similarly, the IC 200 includes an IC chip 220 situated within an IC package 210. The IC chip 220 includes a PMU manager 232, a PMU 234, a set of clock sources 236, a debug interface 240, and IC cores 250. Additionally, the IC 200 further includes a secondary debug interface 242 coupled to the PMU manager 232.

The secondary debug interface 242 is enabled in all power states. Thus, in the particular low power state in which the debug interface 240 is disabled, the PMU manager 232 may communicate debug information (e.g., power state and event information) to a test equipment via the secondary debug interface 242 to facilitate operational verification and debugging of the IC 200. However, the secondary debug interface 242 requires at least one additional dedicated pin/pad, and also consumes more power in the low power state, which can often defeat the purpose of the particular low power state of the IC 200.

In summary, one concept described herein relates to using a power rail (e.g., an existing power rail) to send debug information concerning the PMU 134 (e.g., power state and event information) outside of an IC by impressing a data signal on the power rail. The power rail may be coupled to a pin of the IC for connecting an external decoupling capacitor to the power rail. Accordingly, in a low power state in which the debug interface is disabled, the debug information may be communicated to an external test equipment via the existing power rail. As the power rail and pin already exists, implementing circuitry to impress a data signal on the power rail results in minimal impact on IC area usage and power consumption.

Three exemplary implementations are described herein that includes circuitry for impressing the debug information on a power rail of the IC. One implementation includes circuitry for modulating a voltage on the power rail with the debug information. Another implementation includes circuitry for generating a defined noise profile modulated by the debug information on the power rail. Yet another implementation includes circuitry for modulating a current on the power rail with the debug information. The aforementioned concepts are explained below with reference to the following exemplary implementations.

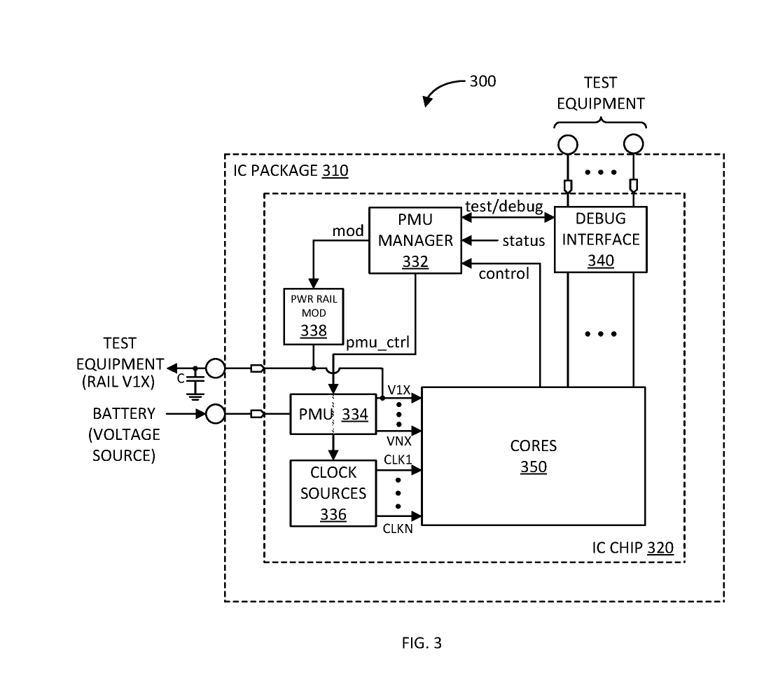

FIG. 3 illustrates a block diagram of an exemplary IC 300 in accordance with another aspect of the disclosure. Similarly, the IC 300 includes an IC chip 320 situated within an IC package 310. The IC chip 320 includes a PMU manager 332, a PMU 334, clock sources 336, a debug interface 340, and IC cores 350. Additionally, the IC 300 further includes a power rail modulator 338 coupled between the PMU manager 332 and a power rail V1X. The power rail V1X is coupled to a pin of the IC 300, which is used for connecting a decoupling capacitor C to the power rail V1X as shown.

When the IC 300 is configured in a low power state in which the debug interface 340 is disabled, the PMU manager 332 is able to send debug information outside of the IC 300 (e.g., to an external test equipment) via the power rail modulator 338, which modulates a parameter (e.g., voltage, noise, current, or other) on the power rail V1X with the debug information. Details of some implementation examples of the power rail modulator 338 are discussed below. An external test equipment, coupled to the power rail pin, demodulates the debug information. The power rail modulator 338 may be an existing circuitry (e.g., an auxiliary regulator) in the IC 300 or may be added to the IC 300, as discussed below in more detail.

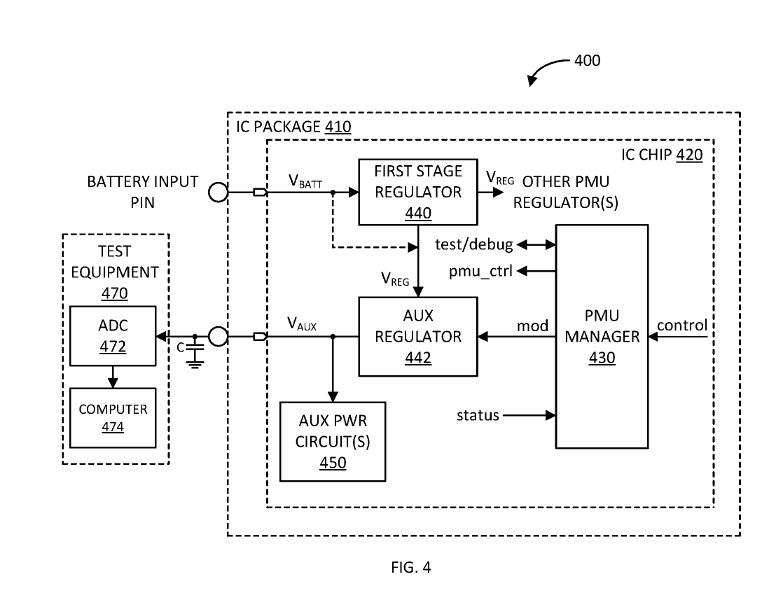

FIG. 4 illustrates a block diagram of an exemplary IC 400 in accordance with another aspect of the disclosure. In this example, the IC 400 includes circuitry for modulating a voltage on a power rail with debug information. In particular, the IC 400 includes an IC chip 420 situated within an IC package 410.

More specifically, the IC chip 420 includes a PMU manager 430, which may be in the form of a state machine or small processor. As previously discussed, the PMU manager 430 may include an input for receiving control commands requesting particular power states from one or more cores of the IC 400. The PMU manager 430 also includes another input for receiving a status signal from a sensor or event-triggering device. Additionally, the PMU manager 430 includes an input/output for receiving one or more test commands from an external test equipment via a debug interface and sending debug information to the test equipment via the debug interface. Further, the PMU manager 430 includes an output for generating a PMU control signal pmu_ctrl for controlling an associated PMU. In addition, as discussed in more detail herein, the PMU manager 430 includes an output for generating a modulation signal (mod) for modulating a voltage V_{AUX} on an auxiliary (AUX) power rail with debug information.

The IC chip 420 further includes a first stage voltage regulator 440 for generating a regulated voltage V_{REG} from a battery voltage V_{BATT}. Accordingly, the first stage voltage regulator 440 includes an input for receiving the battery voltage V_{BATT} from an external battery coupled to an input pin of the IC 400. The regulated voltage V_{REG} may be provided to one or more second stage PMU regulators in the IC chip 420 including an auxiliary (AUX) regulator 442. Alternatively, the battery input pin may be coupled directly to the AUX regulator 442 as indicated by the dashed line. In such case, the battery voltage V_{BATT} is provided directly to an input of the AUX regulator 442.

The AUX regulator 442 generates a regulated AUX voltage V_{AUX} on an AUX power rail based on the regulated voltage V_{REG} or the battery voltage V_{BATT}. The AUX power rail is coupled to an AUX pin of the IC 400. The AUX power rail provides the auxiliary voltage V_{AUX} to a set of one or more AUX powered circuits 450 of the IC 400. An external decoupling capacitor C is coupled between the AUX pin and ground. The AUX regulator 442, AUX pin, and AUX powered circuit(s) 450 may be existing circuitry of the IC 400.

As mentioned, the PMU manager 430 generates a modulation signal including debug information (e.g., power state and event information). The modulation signal is applied to a trim input of the AUX regulator 442. The AUX regulator 442 generates the AUX voltage V_{AUX} on the AUX power rail also based on the modulation signal. Thus, the AUX regulator 442 generates AUX voltage V_{AUX} on the AUX power rail modulated with the debug information via the modulation signal applied to the trim input by the PMU manager 430. The modulation of the AUX voltage V_{AUX} may be small enough that it does not adversely affect the operation of the AUX powered circuit(s) 450 receiving the voltage V_{AUX}. For example, the modulation may entail amplitude modulation including an amplitude increase of the voltage V_{AUX} of 25 mV to indicate a logic “1” and an amplitude decrease of the voltage V_{AUX} of 25 mV to indicate a logic “0”, or vice-versa.

An external test equipment 470, including an analog-to-digital converter (ADC) 472 and a computer 474, may probe the AUX pin to obtain the debug information. That is, the ADC 472 digitizes the modulated AUX voltage V_{AUX}. The digitized modulated voltage is provided to the computer 474. The computer 474 demodulates the digitized modulated voltage to obtain the debug information.

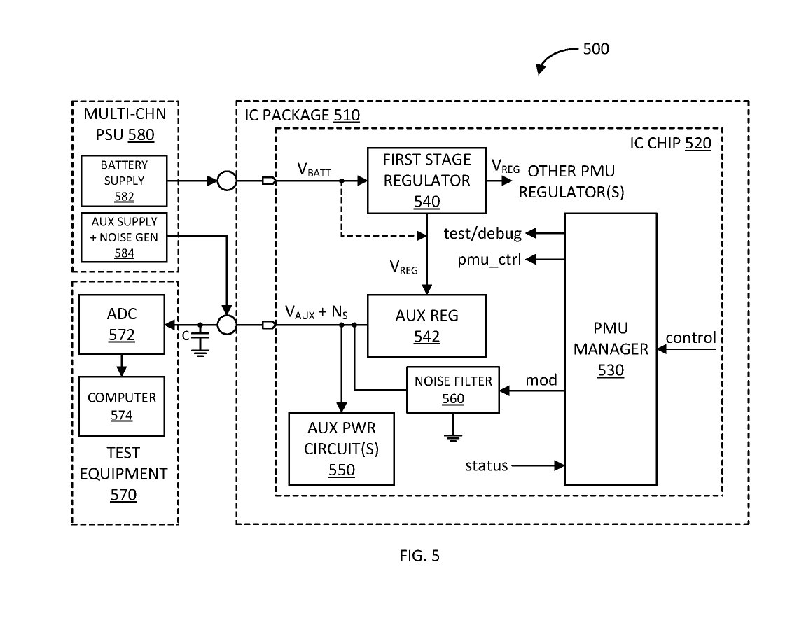

FIG. 5 illustrates a block diagram of an exemplary IC 500 in accordance with another aspect of the disclosure. In this example, the IC 500 includes circuitry for modulating a defined noise injected into a power rail with debug information.

Similarly, the IC 500 includes an IC chip 520 situated within an IC package 510. The IC chip 520 includes a PMU manager 530, a first stage regulator 540, an AUX regulator 542, and a set of one or more AUX powered circuits 550. As in the previous embodiment, the first stage regulator 540 generates a regulated voltage V_{REG} based on a battery voltage V_{BATT}. As the IC 500 may be undergoing a test operation, the battery voltage V_{BATT} may be generated by a battery supply source 582 of a multi-channel power supply unit (PSU) 580. The regulated voltage V_{REG} is provided to an AUX regulator 542 and to other PMU regulator(s). Alternatively, the battery voltage V_{BATT} may be provided directly to the AUX regulator 542. In non-test operation, the AUX regulator 542 generates an AUX voltage V_{AUX} on an AUX power rail based on V_{REG} or V_{BATT}; the AUX voltage V_{AUX} being supplied to one or more AUX powered circuits 550 via the AUX power rail.

Additionally, the IC chip 520 includes a noise filter 560 coupled between the AUX power rail and ground. The noise filter 560 includes an input for receiving a modulation signal (mod) from the PMU manager 530. The modulation signal includes debug information. In this example, the multi-channel PSU 580 includes an AUX supply with a noise generator 584 configured to generate a voltage V_{AUX} plus a defined noise N_{S} on the AUX power rail via the AUX pin of the IC 500. The voltage V_{AUX} on the AUX power rail is sufficiently high to disable the AUX regulator 542 (e.g., the normal AUX voltage generated by the AUX regulator 542+100 mV).

The PMU manager 530 generates the modulation signal for a filter enable input of the noise filter 560. The modulation signal causes the noise filter 560 to filter the defined noise N_{S} on the AUX power rail in accordance with the debug information. For example, the noise filter 560 is disabled to indicate a logic “1” and enabled to indicate a logic “0”, or vice-versa. This results in a noise profile on the AUX power rail, which is modulated with the debug information.

An external test equipment 570, including an analog-to-digital converter (ADC) 572 and a computer 574, may probe the AUX pin to obtain the debug information. That is, the ADC 572 digitizes the AUX voltage V_{AUX} including the modulated noise N_{S}. The digitized modulated voltage and noise are provided to the computer 574. The computer 574 demodulates the modulated noise to obtain the debug information.

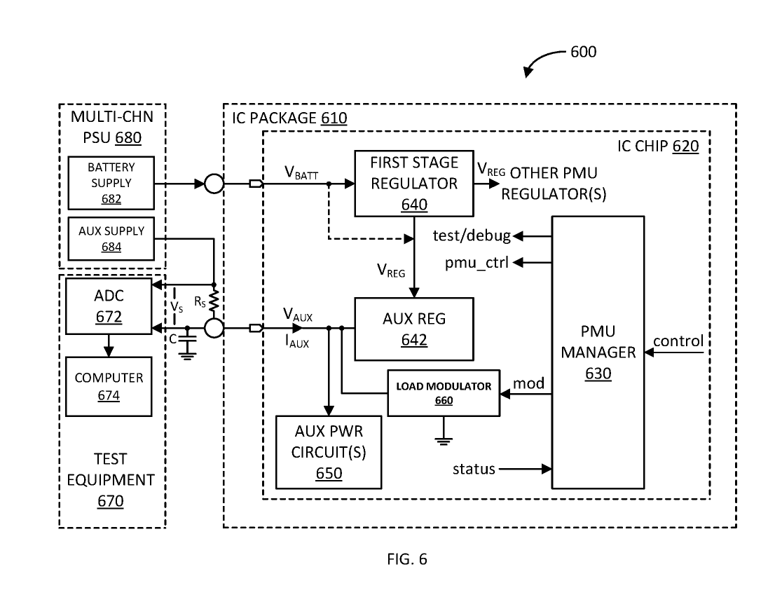

FIG. 6 illustrates a block diagram of another exemplary IC 600 in accordance with another aspect of the disclosure. In this example, the IC 600 includes circuitry for modulating a current on a power rail with debug information.

Similarly, the IC 600 includes an IC chip 620 situated within an IC package 610. The IC chip 620 includes a PMU manager 630, a first stage regulator 640, an AUX regulator 642, and a set of one or more AUX powered circuits 650. As in the previous embodiments, the first stage regulator 640 generates a regulated voltage V_{REG} based on a battery voltage V_{BATT}. As the IC 600 may be undergoing a test operation, the battery voltage V_{BATT} may be generated by a battery supply source 682 of a multi-channel power supply unit (PSU) 680. The regulated voltage V_{REG} is provided to an AUX regulator 642 and to other PMU regulator(s). Alternatively, the battery voltage V_{BATT} may be provided directly to the AUX regulator 642. In non-test operation, the AUX regulator 642 generates an AUX voltage V_{AUX} on an AUX power rail based on V_{REG} or V_{BATT}; the AUX voltage V_{AUX} being supplied to one or more AUX powered circuits 650 via the AUX power rail.

Additionally, the IC chip 620 includes a load modulator 660 coupled between the AUX power rail and ground. The load modulator 660 includes an input for receiving a modulation signal (mod) from the PMU manager 630. The modulation signal includes debug information. In this example, the multi-channel PSU 680 includes an AUX supply 684 configured to generate a voltage V_{AUX} on the AUX power rail via a current-sense resistor R_{S} and the AUX pin of the IC 600. The voltage V_{AUX} on the AUX power rail is sufficiently high to disable the AUX regulator 642 (e.g., the normal AUX voltage generated by the AUX regulator 642+100 mV).

The PMU manager 630 generates the modulation signal for a modulation input of the load modulator 660. The modulation signal causes the load modulator 660 to provide a particular load on the AUX power rail in accordance with the debug information. For example, the load modulator 660 provides a first load impedance to indicate a logic “1” and a second load impedance to indicate a logic “0”. This produces a current I_{AUX} flowing via the AUX power rail modulated with the debug information.

An external test equipment 670, including an analog-to-digital converter (ADC) 672 and a computer 674, may probe the AUX pin to obtain the debug information. That is, the ADC 672 digitizes a sense voltage V_{S} across the sense resistor R_{S}. The sense voltage is related (e.g., proportional) to the modulated current I_{AUX}. The digitized sense voltage is provided to the computer 674. The computer 674 demodulates the digitized sense voltage to obtain the debug information.

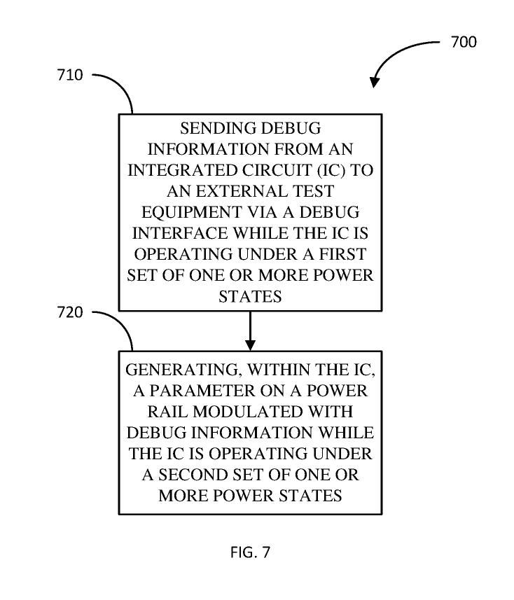

FIG. 7 illustrates a flow diagram of an exemplary method 700 of outputting debug information from an integrated circuit (IC) in accordance with another aspect of the disclosure.

The method 700 includes sending debug information from an integrated circuit (IC) to an external test equipment via a debug interface while the IC is operating under a first set of one or more power states (block 710). An example of a means for sending debug information to an external test equipment via a debug interface while the IC is operating under a first set of one or more power states includes a power management unit (PMU) manager described herein.

The method 700 further includes generating, within the IC, a parameter on a power rail modulated with debug information while the IC is operating under a second set of one or more power states (block 720). An example of a means for generating a parameter on a power rail modulated with debug information while the IC is operating under a second set of one or more power states includes a modulator 338, such as an AUX regulator 442, a noise filter 560, or a load modulator 660 described herein.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An integrated circuit (IC), comprising:
a modulator coupled to a power rail;
a debug interface configured to be enabled while the IC is operating under a first set of one or more power states, and disabled while the IC is operating under a second set of one or more power states; and
a power management unit (PMU) manager configured to:
send debug information to an external test equipment via the debug interface while the IC is operating under the first set of one or more power states; and
generate a modulation signal for the modulator to modulate a parameter on the power rail with the debug information while the IC is operating under the second set of one or more power states.

2. The integrated circuit of claim 1, wherein the modulated parameter comprises a modulated voltage on the power rail.

3. The integrated circuit of claim 1, wherein the modulated parameter comprises a modulated noise on the power rail.

4. The integrated circuit of claim 1, wherein the modulated parameter comprises a modulated current flowing via the power rail.

5. The integrated circuit of claim 1, wherein the modulated parameter comprises a modulated voltage, and wherein the modulator comprises a voltage regulator configured to generate the modulated voltage based on the modulation signal.

6. The integrated circuit of claim 1, wherein the modulated parameter comprises a modulated noise, and wherein the modulator comprises a noise filter configured to generate the modulated noise by filtering a defined noise applied to the power rail based on the modulation signal.

7. The integrated circuit of claim 1, wherein the modulated parameter comprises a modulated current, and wherein the modulator comprises a load modulator configured to generate the modulated current by applying a variable load on the power rail based on the modulation signal.

8. The integrated circuit of claim 1, wherein the debug information comprises a current power state or a history of power states under which the IC is operating or has operated.

9. The integrated circuit of claim 1, wherein the debug information comprises an event which caused the IC to operate under a current power state or a history of events which caused the IC to operate under a history of power states, respectively.

10. The integrated circuit of claim 1, wherein the external test equipment is configured to receive the modulated parameter.

11. A method, comprising:
sending debug information from an integrated circuit (IC) to an external test equipment via a debug interface while the IC is operating under a first set of one or more power states; and
generating, within the IC, a parameter on a power rail modulated with the debug information while the IC is operating under a second set of one or more power states.

12. The method of claim 11, wherein the modulated parameter comprises a modulated voltage on the power rail.

13. The method of claim 11, wherein the modulated parameter comprises a modulated noise on the power rail.

14. The method of claim 11, wherein the modulated parameter comprises a modulated current flowing via the power rail.

15. The method of claim 11, wherein the modulated parameter comprises a modulated voltage, and wherein generating the modulated voltage comprises applying the modulation signal to an input of a voltage regulator.

16. The method of claim 11, wherein the modulated parameter comprises a modulated noise, and wherein generating the modulated noise comprises:
applying a defined noise on the power rail; and
filtering the defined noise based on the modulation signal.

17. The method of claim 11, wherein the modulated parameter comprises a modulated current, and wherein generating the modulated current comprises:
applying a voltage on the power rail; and
varying a load coupled to the power rail based on the modulation signal.

18. The method of claim 11, wherein the debug information comprises a current power state or a history of power states under which the IC is operating or has operated.

19. The method of claim 11, wherein the debug information comprises an event which caused the IC to operate under a current power state or a history of events which caused the IC to operate under a history of power states, respectively.

20. The method of claim 11, further comprising providing the modulated parameter to the external test equipment.

21. An apparatus, comprising:
means for sending debug information from an integrated circuit (IC) to an external test equipment via a debug interface while the IC is operating under a first set of one or more power states; and
means for generating, within the IC, a parameter on a power rail modulated with debug information while the IC is operating under a second set of one or more power states.

22. The apparatus of claim 21, wherein the modulated parameter comprises a modulated voltage on the power rail.

23. The apparatus of claim 21, wherein the modulated parameter comprises a modulated noise on the power rail.

24. The apparatus of claim 21, wherein the modulated parameter comprises a modulated current flowing via the power rail.

25. The apparatus of claim 21, wherein the modulated parameter comprises a modulated voltage, and wherein the means for generating the modulated voltage comprises means for applying the modulation signal to an input of a voltage regulator.

26. The apparatus of claim 21, wherein the modulated parameter comprises a modulated noise, and wherein the means for generating the modulated noise comprises:
means for applying a defined noise on the power rail; and
means for filtering the defined noise based on the modulation signal.

27. The apparatus of claim 21, wherein the modulated parameter comprises a modulated current, and wherein the means for generating the modulated current comprises:
means for applying a voltage on the power rail; and
means for varying a load coupled to the power rail based on the modulation signal.

28. The apparatus of claim 21, wherein the debug information comprises a current power state or a history of power states under which the IC is operating or has operated.

29. The apparatus of claim 21, wherein the debug information comprises an event which caused the IC to operate under a current power state or a history of events which caused the IC to operate under a history of power states, respectively.

30. The apparatus of claim 21, further comprising means for providing the modulated parameter to the external test equipment.
